(19) United States
(12) Patent Application Publication
(10) Pub. No.: US 2022/0110231 A1
(43) Pub. Date: Apr. 7, 2022

(54) ELECTROMAGNETIC FIELD RADIATION AND ANTI-MICROBIAL PROTECTION CASE ASSEMBLY FOR ELECTRONIC DEVICES

(71) Applicant: Pranav Bollapragada, Folsom, CA (US)

(72) Inventor: Pranav Bollapragada, Folsom, CA (US)

(21) Appl. No.: 17/151,276

(22) Filed: Jan. 18, 2021

Related U.S. Application Data
(60) Provisional application No. 63/127,152, filed on Dec. 18, 2020.
(60) Provisional application No. 63/088,009, filed on Oct. 6, 2020.

(51) Int. Cl. H05K 9/00; A45C 11/00

(52) U.S. Cl. CPC H05K 9/0084; H05K 9/0086; A45C 2011/003; A45C 2011/002; A45C 11/00

(57) ABSTRACT

The disclosure relates to an electronic device case assembly for providing protection against electromagnetic field radiation and microbes. The case assembly includes a case configured to receive an electronic device and have a sealed pocket. The case assembly further includes at least one electromagnetic field radiation attenuating layer. The electromagnetic field radiation attenuating layer is embedded within the sealed pocket of the case. The electromagnetic field radiation attenuating layer is made of material selected from the group consisting of aluminium, silver, copper and zinc. The case assembly further includes a coat of material selected from the group consisting of silver ions, copper ions and charcoal powder on the case in order to eliminate the microbes.

### FIELD OF THE INVENTION

The embodiments of the present invention generally relate to a case assembly for electronic devices, and more particularly, the embodiments of the present invention relate to a case assembly that provides protection against electromagnetic field radiation emitted by the electronic devices and eliminates any microbes that come in contact with the case assembly.

### BACKGROUND OF THE INVENTION

Electronic devices such as cell phones and tablets have become an integral part of our daily lives. We have become so used to these devices that now it is almost next to impossible to live without them. Though these devices offer a lot of advantages, and have definitely made our life easier, there are a few drawbacks that come along with it. One of the drawbacks of using cell phones and tablets is that they generate Electromagnetic Field (EMF) radiation. This type of radiation is also referred to as Radio Frequency (RF) energy. Research has shown that the radiation emitted from cell phones and tablets has various deleterious effects on human health. Currently, there are certain technologies that help in blocking the EMF radiation emitted by these electronic devices. The existing technologies include external or bolted-on attachments. These are additional accessories that are mounted on the existing cell phone case. Few problems associated with such accessories are that they compromise the aesthetics of the case which the customer uses. Further, these accessories have lesser life and eventually detach from the case. This leads to user buying a new accessory for mounting on the cell phone case.

In view of the above, there remains a need for a novel and inventive case assembly for electronic devices that can limit the electromagnetic field radiation emitted by the electronic device and eliminate the microbes that come in contact with the case assembly.

### OBJECT OF THE INVENTION

An object of the present invention is to provide a case assembly for electronic devices that attenuates the electromagnetic field radiation emitted from the electronic devices. Another object of the present invention is to provide a case assembly for electronic devices that provides anti-microbial protection to the user.

Another object of the present invention is to provide a case assembly for electronic devices that can maintain the temperature of the electronic devices at a suitable range. Another object of the present invention is to provide a case assembly for electronic devices that is long lasting.

### SUMMARY OF THE INVENTION

According to an exemplary embodiment of the invention, an electronic device case assembly for providing protection against electromagnetic field radiation and microbes is disclosed. The case assembly includes a case configured to receive an electronic device and have a sealed pocket. The case assembly further includes at least one electromagnetic field radiation attenuating layer. The electromagnetic field radiation attenuating layer is embedded within the sealed pocked of the case. The electromagnetic field radiation attenuating layer is made of material selected from the group consisting of aluminum, silver, copper and zinc. The case assembly further includes a coat of a material selected from the group consisting of silver ions, copper ions and charcoal powder applied on the case in order to eliminate the microbes.

It is to be understood that both the foregoing general description and the following detailed description are exemplary and explanatory only and are not restrictive of the invention, as claimed.

### BRIEF DESCRIPTION OF THE DRAWINGS

So that the manner in which the above recited features of the present invention can be understood in detail, a more particular description of the invention, briefly summarized above, may have been referred by embodiments, some of which are illustrated in the appended drawings. It is to be noted, however, that the appended drawings illustrate only typical embodiments of this invention and are therefore not to be considered limiting of its scope, for the invention may admit to other equally effective embodiments.

These and other features, benefits, and advantages of the present invention will become apparent by reference to the following figures, with like reference numbers referring to like structures across the views, wherein:

FIG. 1 illustrates a perspective view of an electronic device back case assembly, in accordance with an exemplary embodiment of the present invention;

FIG. 2 illustrates a perspective view of the opened electronic device back case assembly with electromagnetic field radiation attenuating layer, in accordance with an exemplary embodiment of the present invention;

FIG. 3 illustrates a perspective view of the opened electronic device back case assembly with electromagnetic field radiation attenuating layers, in accordance with an exemplary embodiment of the present invention;

FIG. 4 illustrates a perspective view of an electronic device foldable case assembly, in accordance with another exemplary embodiment of the invention.

FIG. 5 illustrates an exploded view of the electronic device foldable case assembly with one electromagnetic field radiation attenuating layer, in accordance with another exemplary embodiment of the invention.

FIG. 6 illustrates an exploded view of the electronic device foldable case assembly with two electromagnetic field radiation attenuating layers, in accordance with another exemplary embodiment of the present invention.

### DETAILED DESCRIPTION OF THE PREFERRED EMBODIMENTS

While the present invention is described herein by way of example using embodiments and illustrative drawings, those skilled in the art will recognize that the invention is not limited to the embodiments of drawing or drawings described, and are not intended to represent the scale of the various components. Further, some components that may form a part of the invention may not be illustrated in certain figures, for ease of illustration, and such omissions do not limit the embodiments outlined in any way. It should be understood that the drawings and detailed description thereto are not intended to limit the invention to the particular form disclosed, but on the contrary, the invention is to cover all modifications, equivalents, and alternatives falling within the scope of the present invention as defined by the appended claim. As used throughout this description, the word “may” is used in a permissive sense (i.e. meaning having the potential to), rather than the mandatory sense, (i.e. meaning must). Further, the words “a” or “an” mean “at least one” and the word “plurality” means “one or more” unless otherwise mentioned. Furthermore, the terminology and phraseology used herein is solely used for descriptive purposes and should not be construed as limiting in scope. Language such as “including,” “comprising,” “having,” “containing,” or “involving,” and variations thereof, is intended to be broad and encompass the subject matter listed thereafter, equivalents, and additional subject matter not recited, and is not intended to exclude other additives, components, integers or steps. Likewise, the term “comprising” is considered synonymous with the terms “including” or “containing” for applicable legal purposes. Any discussion of documents, acts, materials, devices, articles and the like is included in the specification solely for the purpose of providing a context for the present invention. It is not suggested or represented that any or all of these matters form part of the prior art base or were common general knowledge in the field relevant to the present invention.

In this disclosure, whenever a composition or an element or a group of elements is preceded with the transitional phrase “comprising”, it is understood that we also contemplate the same composition, element or group of elements with transitional phrases “consisting of”, “consisting”, “selected from the group of consisting of, “including”, or “is” preceding the recitation of the composition, element or group of elements and vice versa.

The present invention is described hereinafter by various embodiments with reference to the accompanying drawings, wherein reference numerals used in the accompanying drawings correspond to the like elements throughout the description. This invention may, however, be embodied in many different forms and should not be construed as limited to the embodiment set forth herein. Rather, the embodiment is provided so that this disclosure will be thorough and complete and will fully convey the scope of the invention to those skilled in the art.

According to an embodiment of the present invention, an electronic device case assembly is disclosed. The electronic device case assembly (hereinafter referred to as ‘case assembly’) may be used to hold various types of electronic devices such as, but not limited to, cell phones, tablets, laptops etc. The embodiments disclosed herein illustrate case assembly for a cell phone. However, it will be apparent to a person skilled in the art that the case assembly may be used for other electronic devices as well. The case assembly may be primarily used for electronic devices that emit Electromagnetic Field (EMF) radiation. In other words, the case assembly may be used to attenuate the EMF radiation emitted by the electronic devices. Further, the case assembly may eliminate various harmful microbes or viruses that come in contact with the case assembly. A person skilled in the art will appreciate that the present invention provides protection to a user from harmful EMF radiation and microbes.

The case assembly may be of various shapes and sizes depending on the electronic device it is supposed to hold. For example, a case assembly for holding a cell phone will be smaller in size compared to a case assembly for holding a tablet. Moreover, each case assembly may be manufactured according to the design and model of the cell phones, tablets, laptops etc. It should be noted that the case assembly can be of various types. For example, according to an embodiment, the case assembly may be a back case assembly and according to another embodiment, the case assembly may be a foldable case assembly.

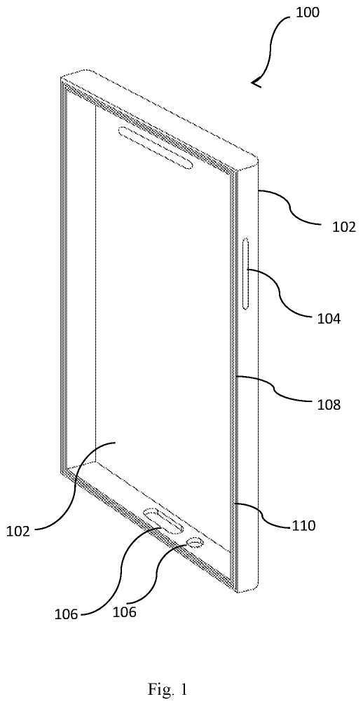

FIG. 1 illustrates a perspective view of an electronic device back case assembly 100, in accordance with an exemplary embodiment of the present invention. The back case assembly 100 may include a case 102. The case 102 may be configured to receive an electronic device. In certain embodiments, the case 102 may encase the electronic device from the top, bottom, left side, right side, and rear of the electronic device. In some embodiments, the case 102 may encase the electronic device from at least the rear of the electronic device. It should be noted that besides providing protection against EMF radiation and microbes, the back case assembly 100 may also provide protection from sudden impacts caused due to falling.

The case 102 may form the outermost layer of the back case assembly 100. In other words, the case 102 may form the covering layer of the back case assembly 100. The case 102 may be a single body formed via a molding process. According to an embodiment, the case 102 may be made of rubber. According to another embodiment, the case 102 may be made of plastic. It will be apparent to a person skilled in the art that the shape and size of the case 102 may vary according to the shape and size of the electronic device it is supposed to hold. The case 102 may further include provisions 104 for accessing the volume buttons and power button of the electronic device. For example, in a cell phone, the volume buttons and the power button are usually provided on either the top or the sides. Accordingly, the case 102 may have slots to access the volume buttons and the power button. Further, the cell phones may include ports for connecting headphones and charger. The case 102 may include slots 106 at the respective positions for accessing the ports and connecting the headphones and charger to the cell phone.

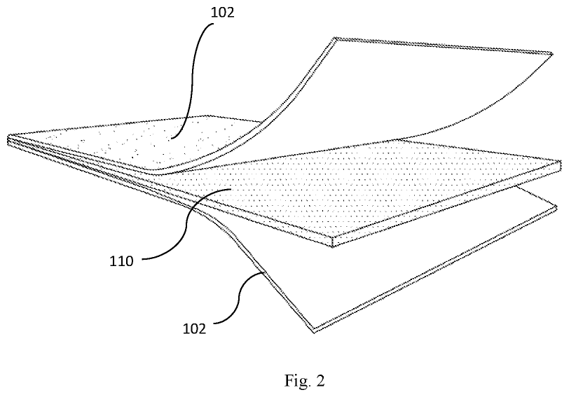

FIG. 2 illustrates a perspective view of an opened electronic device back case assembly 100, in accordance with an exemplary embodiment of the invention. The case 102 may have a sealed pocket 108 in which an Electromagnetic Field (EMF) radiation attenuating layer 110 is embedded. It should be noted that the size and shape of the pocket 108 may vary according to the size and shape of the EMF radiation attenuating layer 110 embedded within the pocket. In a preferred embodiment, the EMF radiation attenuating layer 110 may be of the same size as the size of the case 102. In certain embodiments, the EMF radiation attenuating layer 110 may be small cut-outs arranged at specific area of the case 102. The EMF radiation attenuating layer 110 may be embedded adjacent to the position of antenna in the cell phone. A person skilled in the art will appreciate that the EMF radiation attenuating layer 110 may be arranged adjacent to the antenna, as the antenna emits EMF radiation. It should be further noted that the EMF radiation attenuating layer 110 may be embedded within the pocket 108 during the molding process itself. In other words, the EMF radiation attenuating layer 110 may be non removable from the case 102 when the case 102 is manufactured.

As described above, the EMF radiation attenuating layer 110 may attenuate the EMF radiation emitted by the electronic device. The EMF radiation attenuating layer 110 may act as an EMF protection barrier without weakening the signal received by the electronic device. In some embodiments, the EMF radiation attenuating layer 110 may be made of aluminium. In an embodiment, the EMF radiation attenuating layer 110 may be an aluminium foil. The aluminium EMF radiation attenuating layer 110a may also act as a thermal shield. It will be apparent to a person skilled in the art that the thermal shield may be a heat shield or a cold shield. The aluminium EMF radiation attenuating layer 110a may enable the electronic device to maintain its temperature at a suitable range. A person skilled in the art will appreciate that the thermal shield will prevent extreme cooling or heating of the electronic device. In certain embodiments, the EMF radiation attenuating layer 110 may be a mesh fabric 110b made of a material selected from the group consisting of pure silver, pure copper and pure zinc.

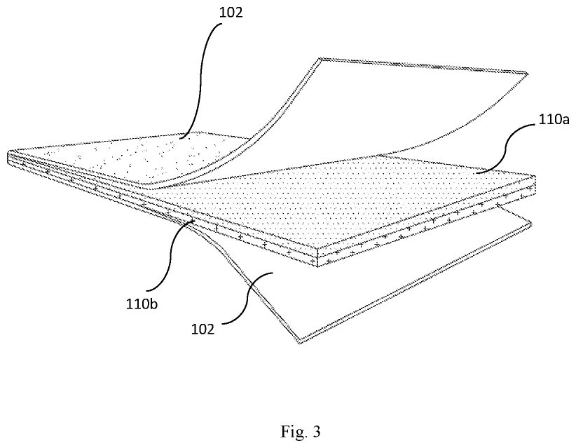

According to an embodiment, the EMF radiation attenuating layer 110 embedded within the pocket 108 may be a single layer made of aluminium. According to another embodiment, the EMF radiation attenuating layer 110 may be a single layer of one of pure silver, pure copper and pure zinc. According to yet another embodiment, the EMF radiation attenuating layer 110 may be a plurality of layers made from the group consisting of aluminium, pure silver, pure copper and pure zinc. A perspective view of an opened electronic device back case assembly 100 with two layers 110a, 110b is shown in FIG. 3.

The back case assembly 100 may further include a coat of material selected from the group consisting of zinc ions, copper ions and charcoal powder on the case 102. The zinc ions or copper ions or charcoal power may be applied on the case 102 by any means known in the art. In an embodiment, the zinc ions or the copper ions may be sprayed on the case 102. It should be noted that the zinc ions or copper ions or charcoal powder may be applied on the entire surface of the case 102. The zinc ions, copper ions and charcoal powder may eliminate any microbes or virus coming in contact with the case 102. Accordingly, the back case assembly 100 may provide anti-viral and anti-microbial protection to the users.

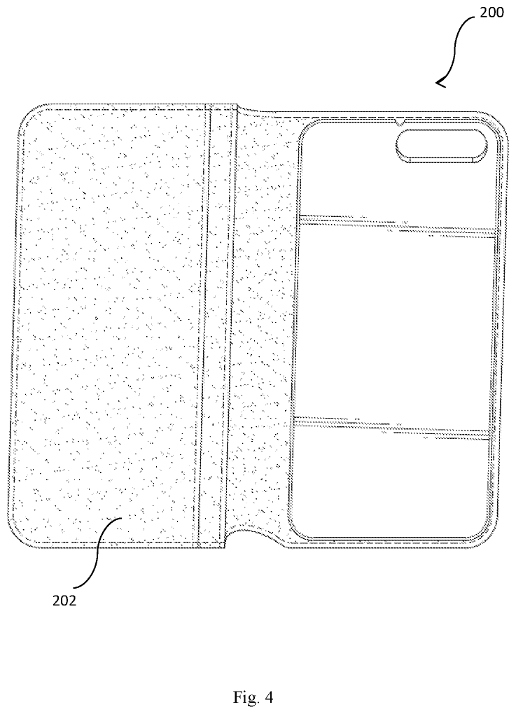

FIG. 4 illustrates a perspective view of an electronic device foldable case assembly 200 in accordance with another embodiment of the invention. The foldable case assembly 200 may include a case 202. The case 202 may form the outer covering of the foldable case assembly 200. According to an embodiment, the case 202 may directly receive an electronic device. According to another embodiment, the case 202 may receive the electronic device via a holder (not shown in FIG.) attached to the case 202. In certain embodiments, the case 202 may encase the electronic device from the top, bottom, left side, right side, front and rear of the electronic device. In some embodiments, the case 202 may encase the electronic device from at least the front and the rear of the electronic device. According to an embodiment, the case 202 may be made of leather. According to another embodiment, the case 202 may be made of a fabric. According to yet another embodiment, the case may be made by sewing both the leather and fabric. For example, when a case 202 is made by sewing both leather and fabric, the leather may form the external part of the case 202 and the fabric may form the internal part of the case 202. A person skilled in the art will appreciate that the case assembly 200 shown in FIG. 1 is for illustration purposes only and foldable case assembly 200 having other shape, size and design may also be implemented.

The case 202 may include a sealed pocket 204. The pocket 204 may be sealed along with an EMF radiation attenuating layer 206 during the manufacturing process itself. For example, in the foldable case assembly 200, the EMF radiation attenuating layer 206 may be embedded within the pocket 204 during the sewing process of the case 202. The EMF radiation attenuating layer 206 may limit the EMF radiation emitted by the electronic device. The EMF radiation attenuating layer 206 may act as an EMF protection barrier without weakening the signal received by the electronic device. In some embodiments, the EMF radiation attenuating layer 206 may be made of aluminium. In an embodiment, the EMF radiation attenuating layer 206 may be an aluminium foil. The aluminium EMF radiation attenuating layer 206a may also act as a thermal shield. The aluminium EMF radiation attenuating layer 206a may enable the electronic device to maintain its temperature at a suitable range. A person skilled in the art will appreciate that the thermal shield will prevent extreme cooling or heating of the electronic device.

In some embodiments, the EMF radiation attenuating layer 206 may be a mesh fabric 206b made of one of pure silver or pure copper or pure zinc. The EMF radiation attenuating layer 206 made of one of pure silver or pure copper or pure zinc may attenuate the EMF radiation without weakening the signal.

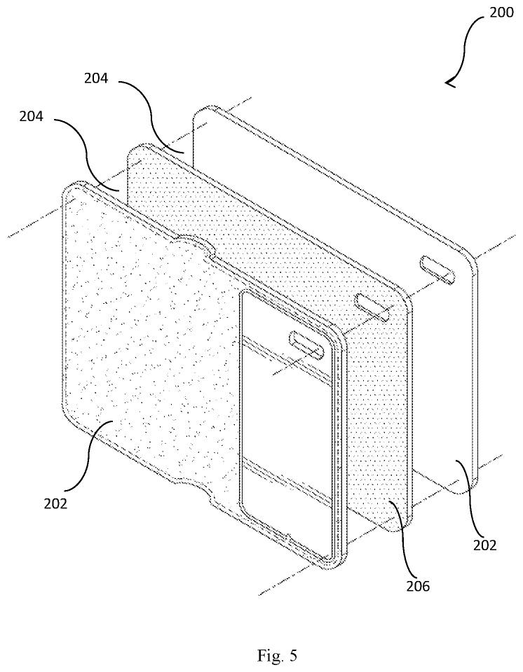

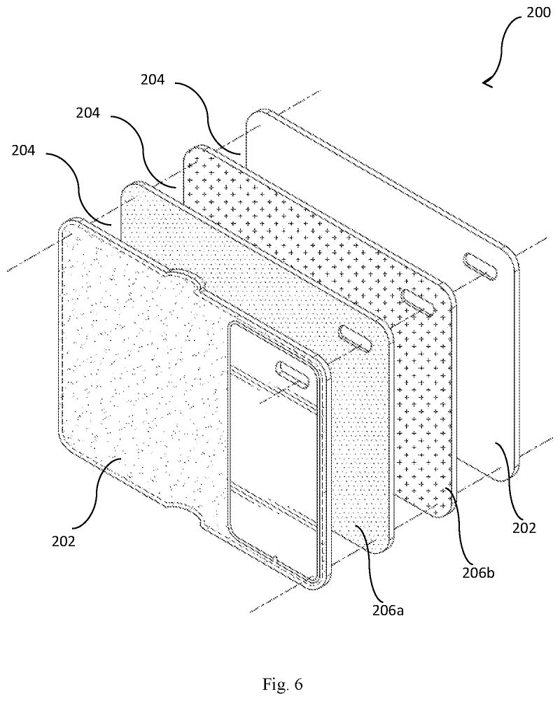

FIG. 5 illustrates an exploded view of the electronic device foldable case assembly 200 with one EMF radiation attenuating layer 206, in accordance with another exemplary embodiment of the invention. According to an embodiment, the EMF radiation attenuating layer 206 embedded within the pocket may be a single layer made of aluminium. According to another embodiment, the EMF radiation attenuating layer 206 may be a single layer of one of pure silver, pure copper and pure zinc. According to yet another embodiment, the EMF radiation attenuating layer 206 may be a plurality of layers made from the group consisting of aluminium, pure silver, pure copper and pure zinc. An exploded view of the foldable case assembly 200 with two EMF radiation attenuating layers 206a, 206b is shown in FIG. 6.

The foldable case assembly 200 may further include a coat of at least one of zinc ions, copper ions and charcoal powder coated on the case 202. The zinc ions or copper ions or charcoal power may be applied on the case 202 by any means known in the art. In an embodiment, the zinc ion or the copper ions may be sprayed on the case 202. It should be noted that the zinc ion or copper ion or charcoal powder may be applied on entire surface of the case 202. The zinc ions, copper ions and charcoal powder may eliminate any virus or microbes coming in contact with the case 202. Accordingly, the foldable case assembly 200 may provide anti-viral and anti-microbial protection to the users.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope of consistent with the principles and the novel and inventive features disclosed or suggested herein. Accordingly, the invention is anticipated to hold on to all other such alternatives, modifications, and variations that fall within the scope of the present invention and appended claims.

What is claimed is:

1. An electronic device case assembly for providing protection against electromagnetic field radiation and microbes, the electronic device case assembly comprising:
a case configured to receive an electronic device, wherein the case have a sealed pocket;
at least one electromagnetic field radiation attenuating layer, wherein the at least one electromagnetic field radiation attenuating layer is embedded within the sealed pocket, and wherein the at least one electromagnetic field radiation attenuating layer is made of a material selected from the group consisting of aluminium, silver, copper and zinc; and
a coat of at material selected from the group consisting of zinc ions, copper ions and charcoal powder is coated on the case.

2. The electronic device case assembly as claimed in claim 1, wherein the electronic device is one of a cell phone, tablet and laptop.

3. The electronic device case assembly as claimed in claim 1, wherein the at least one electromagnetic field radiation attenuating layer is a thermal shield made of aluminium foil.

4. The electronic device case assembly as claimed in claim 1, wherein the at least one electromagnetic field radiation attenuating layer is a fabric mesh made of one of pure silver, pure copper and pure zinc.

5. The electronic device case assembly as claimed in claim 1, wherein the case assembly is a back case assembly that is configured to encase the top, bottom, left side, right side and the rear of the electronic device.

6. The electronic device case assembly as claimed in claim 1, wherein the case assembly is a foldable case assembly that is configured to encase the top, bottom, left side, right side, rear and the front of the electronic device.

7. The electronic device case assembly as claimed in claim 1, wherein the at least one electromagnetic field radiation attenuating layer is embedded in the sealed pocket during the molding of the case.

8. The electronic device case assembly as claimed in claim 1, wherein the at least one electromagnetic field radiation attenuating layer is sewn inside the sealed pocket of the case.

9. The electromagnetic case assembly as claimed in claim 1, wherein the case is made of at least one of a leather, fabric, rubber and plastic.
